(19) United States
(12) Patent Application Publication
(10) Pub. No.: US 2009/0310105 A1
(43) Pub. Date: Dec. 17, 2009

(54) Optical member, interferometer system, stage apparatus, exposure apparatus, and device manufacturing method

(75) Inventor: Yosuke Kuriyama, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/149,080

(22) Filed: Apr. 25, 2008

Related U.S. Application Data
(60) Provisional application No. 60/924,383, filed on May 11, 2007.

(30) Foreign Application Priority Data
Apr. 27, 2007 (JP) 2007-120335

(51) Int. Cl. G03F 7/20; G01B 11/14; G01B 9/02; G03B 27/50

(52) U.S. Cl. 355/50; 356/614; 356/498

(57) ABSTRACT

An optical member is irradiated with light in order to measure position information in a first direction. The optical member has a first reflecting surface, onto which light propagating in a second direction intersecting the first direction is incident, and a second reflecting surface, onto which light propagating in the second direction is incident. The first reflecting surface and second reflecting surface are optically connected, and light reflected by one among the first reflecting surface and second reflecting surface is incident on the other reflecting surface.

### CROSS-REFERENCE TO RELATED APPLICATION

This application is a non-provisional application claiming priority to and the benefit of U.S. provisional application No. 60/924,383, filed May 11, 2007. Furthermore, this application claims priority to Japanese Patent Application No. 2007-120335, filed Apr. 27, 2007. The entire contents of which are incorporated herein by reference.

### BACKGROUND

1. Field of the Invention

This invention relates to an optical member, interferometer system, stage apparatus, exposure apparatus, and device manufacturing method.

2. Related Art

An exposure apparatus used in lithography processes is provided with a stage which holds a photosensitive substrate while being irradiated with exposure light. Position information for this stage is often measured using an interferometer system. Japanese Patent Application Publication No. 2005-233966 A and PCT International Patent Publication WO 2007/001017 disclose examples of technology related to such interferometer systems.

In an interferometer system, a reflecting surface of an optical member positioned on the stage is irradiated with light (a beam), and the light reflected by the reflecting surface is used to measure position information for the stage. If the optical member positioned on the stage is made large, the stage mass may be increased. As a result, for example, the acceleration performance of the stage is diminished, and the load on the driving apparatus used to move the stage may be increased.

A purpose of the present invention is to provide an optical member the size of which is kept small, and which enables satisfactory execution of position measurement of a stage or other mobile body. Another purpose is to provide an interferometer system the size of which is kept small, and which enables satisfactory execution of position measurement of a mobile body, and a stage apparatus and exposure apparatus provided with such an interferometer system. Still another purpose is to provide a device manufacturing method enabling satisfactory manufacture of devices.

### SUMMARY

According to a first aspect of the invention, an optical member, which is irradiated by light to measure position information in a first direction is provided, having a first reflecting surface onto which light propagating in a second direction intersecting the first direction is incident, and a second reflecting surface onto which light propagating in the second direction is incident; the first reflecting surface and second reflecting surface are optically connected, and light reflected by one among the first reflecting surface and the second reflecting surface is incident on the other reflecting surface.

By means of the first aspect of the invention, the size can be kept small, and satisfactory execution of position measurement of a mobile body is possible.

According to a second aspect of the invention, an interferometer system, which measures position information of a mobile body in a first direction, has a first emission portion which emits measurement light; a second emission portion which emits reference light; a first reflecting surface, positioned on the mobile body, onto which the measurement light from the first emission portion, propagating in a second direction intersecting the first direction, is incident; a second reflecting surface, positioned on the mobile body, onto which reference light from the second emission portion, propagating in the second direction, is incident; a third reflecting surface, optically connected to the second reflecting surface, in a first position, and which is substantially stationary; and a fourth reflecting surface, optically connected to the first reflecting surface, in a second position, and which is substantially stationary; the first reflecting surface and second reflecting surface are optically connected, and light reflected by one among the first reflecting surface and the second reflecting surface is incident on the other reflecting surface.

By means of the second aspect of the invention, the size can be kept small, and satisfactory execution of position measurement of a mobile body is possible.

According to a third aspect of the invention, a stage apparatus is provided, having a stage, which is movable in a prescribed plane substantially perpendicular to a first direction, and the optical member of the first aspect, positioned on the stage.

By means of the third aspect of the invention, the stage can be moved satisfactorily.

According to a fourth aspect of the invention, a stage apparatus is provided, having a stage, which is movable in a prescribed plane substantially perpendicular to a first direction, and the interferometer system of the second aspect, to measure position information for the stage in the first direction.

By means of the fourth aspect of the invention, the stage can be moved satisfactorily.

According to a fifth aspect of the invention, an exposure apparatus which exposes a substrate to exposure light via a mask having a pattern is provided, having a mask stage which moves while holding the mask, and a substrate stage which moves while holding a substrate; at least one among the mask stage and the substrate stage has the stage apparatus of the third or fourth aspect.

By means of the fifth aspect, a stage apparatus which can be moved satisfactorily can be used to expose a substrate.

According to a sixth aspect of the invention, a device manufacturing method is provided, in which the exposure apparatus of the fifth aspect is used to expose a substrate, and the exposed substrate is developed.

By means of the sixth aspect, devices can be manufactured satisfactorily.

According to a seventh aspect of the invention, an interferometer system for measuring a position of a mover along a first axis is provided, the interferometer system comprising: a co-ordinate system comprising the first axis, a second axis, which is orthogonal to the first axis, and a third axis, which is orthogonal to the first axis and the second axis; a first member that is disposed on the mover; a second member and a third member that are disposed apart from the mover along the second axis; a first route for a measurement beam, the first route comprising a successive two time reflection on the first member by which the measurement beam is bent about the third axis, and an at least one time reflection on the second member by which the measurement beam from the first member is returned to the first member; and a second route for a reference beam, the second route comprising a successive two time reflection on the first member by which the reference beam is bent about the third axis, and an at least one time reflection on the third member by which the reference beam from the first member is returned to the first member.

According to some aspects of the present invention, increases in the size of the apparatus can be suppressed, and position measurement of a mobile body can be executed satisfactorily, so that desired devices can be manufactured.

### BRIEF DESCRIPTION OF THE DRAWINGS

FIG. 1 is a schematic diagram showing one example of the exposure apparatus of an embodiment.

FIG. 2 is a perspective view used to explain the interferometer system of an embodiment.

FIG. 3 shows the optical member of an embodiment.

FIG. 4 is a perspective view showing the Z interferometer system of an embodiment.

FIG. 5 is a summary configuration diagram showing the Z interferometer system of an embodiment.

FIG. 6 shows a comparison example.

FIG. 7 shows a modified example of the optical member of an embodiment.

FIG. 8 is a schematic perspective view showing another embodiment of the Z interferometer system.

FIG. 9A is a schematic view showing an embodiment of the roof mirror.

FIG. 9B is a schematic view showing another embodiment of the roof mirror.

FIG. 9C is a schematic view showing another embodiment of the roof mirror.

FIG. 10 is a view schematically showing the change in the optical path of the beam in the Z interferometer system when the attitude of the substrate stage has changed.

FIG. 11 is a flowchart showing an example of microdevice manufacturing processes.

### DESCRIPTION OF EMBODIMENTS

Below, embodiments of the invention are explained referring to the drawings; however, the invention is not limited to these embodiments. In the following explanations, an XYZ orthogonal coordinate system is established, and the positional relationships of members are explained referring to this XYZ orthogonal coordinate system. A prescribed direction in the horizontal plane is taken to be the X-axis direction; the direction in the horizontal plane perpendicular to the X-axis direction is taken to be the Y-axis direction; and the direction perpendicular to both the X-axis direction and the Y-axis direction (that is, the vertical direction) is taken to be the Z-axis direction. The rotation (inclination) directions about the X axis, Y axis, and Z axis are respectively the θX, θY, and θZ directions.

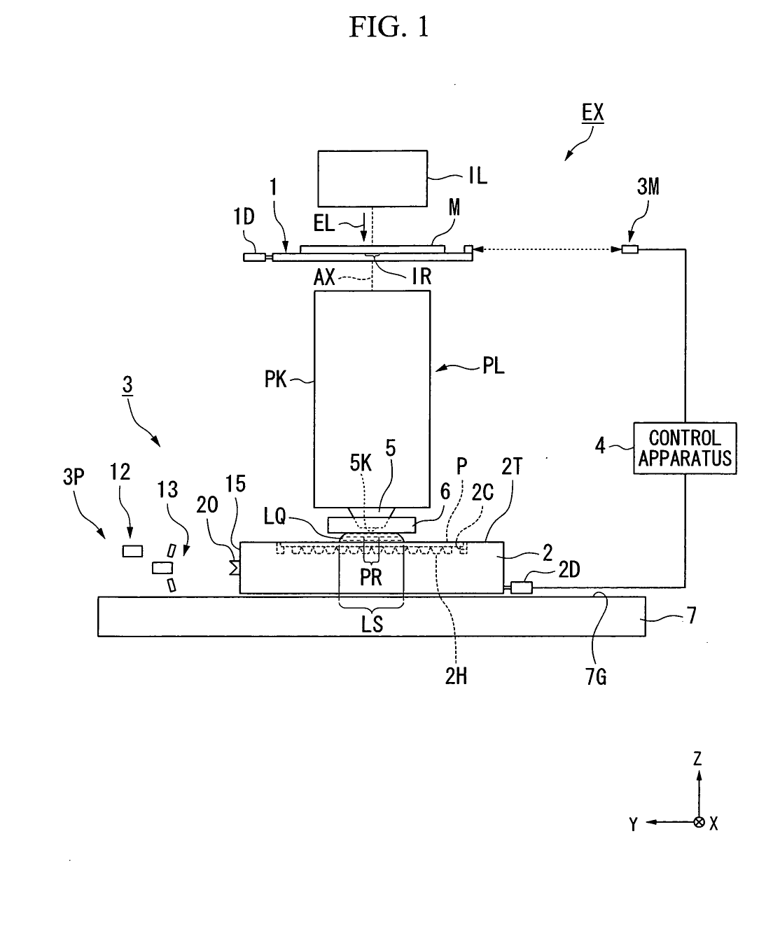

FIG. 1 is a summary configuration diagram showing one example of the exposure apparatus EX of an embodiment. In FIG. 1, the exposure apparatus EX has a mask stage 1, which can move while holding a mask M having a pattern; a substrate stage 2, which can move while holding a substrate P; a first driving system 1D, which can move the mask stage 1; a second driving system 2D, which can move the substrate stage 2; an interferometer system 3, having a laser interferometer which measures position information for the mask stage 1 and substrate stage 2; an illumination system IL, which illuminates the mask M with exposure light EL; a projection optical system PL, which projects an image of the pattern of the mask M, illuminated with exposure light EL, onto the substrate P; and a control apparatus 4, which controls operation of the entire exposure apparatus EX.

Here the substrate P is a substrate used to manufacture devices, and for example includes substrates obtained by forming a photosensitive film on a base such as a silicon wafer or other semiconductor wafer. A photosensitive film is a photoresist film. Further, a protective film (topcoat film) or various other films may be formed on the substrate P, separately from a photosensitive film. The mask M includes reticles on which are formed device patterns for projection onto a substrate P, and may for example be obtained by forming a light shielding film, such as of chromium or similar, in a prescribed pattern on a glass plate or other transparent member. Such transmissive masks are not limited to binary masks in which a pattern is formed by a light shielding film, but includes for example halftone type masks, as well as spatial frequency-modulating and other phase-shifting masks. Further, in this embodiment a transmissive mask is used as the mask M, but a reflective mask may also be used.

In this embodiment, an example is explained in which the exposure apparatus EX is an immersion exposure apparatus which exposes the substrate P with exposure light EL via a liquid LQ. In the embodiment, a liquid immersion space LS is formed such that liquid LQ fills the optical path space of the exposure light EL on the image-plane side of the terminal optical element 5 closest to the image plane of the projection optical system PL, among the plurality of optical elements of the projection optical system PL. The optical path space of the exposure light EL is a space which includes the optical path traversed by the exposure light EL. The liquid immersion space LS is the space filled with liquid LQ. In this embodiment, water (pure water) is used as the liquid LQ.

In the embodiment, the exposure apparatus EX has a liquid immersion member 6 to form the liquid immersion space LS. The liquid immersion member 6 is positioned in proximity to the terminal optical element 5. As the liquid immersion member 6, for example, a member disclosed in PCT International Publication WO 2006/106907 or similar can be used. The liquid immersion space LS is formed between the terminal optical element 5 and liquid immersion member 6, and an object placed in a position opposed to the terminal optical element 5 and liquid immersion member 6. In this embodiment, objects which can be placed in a position opposed to the terminal optical element 5 and liquid immersion member 6 include the substrate stage 2, and the substrate P held by the substrate stage 2.

In this embodiment, the exposure apparatus EX adopts a local liquid immersion method, in which a liquid immersion space LS is formed such that a portion of the region on the substrate P which includes the projection region PR of the projection optical system PL is covered with liquid LQ.

The exposure apparatus EX of this embodiment is a scanning exposure apparatus (a so-called scanning stepper) which, while moving the mask M and substrate P synchronously in a prescribed scanning direction, projects an image of the pattern of the mask M onto the substrate P. During exposure of the substrate P, the mask M and substrate P are moved in a prescribed scanning direction within the XY plane, which intersects the optical axis AX (the optical path of the exposure light EL) of the projection optical system PL, substantially parallel to the Z axis. In this embodiment, the scanning direction of the substrate P (synchronized motion direction) is the Y-axis direction, and the scanning direction of the mask M (synchronized motion direction) is also the Y-axis direction. The exposure apparatus EX moves the substrate P in the Y-axis direction with respect to the projection region PR of the projection optical system PL, and moves the mask M in the Y-axis direction with respect to the illumination region IR of the illumination system IL, synchronized with motion of the substrate P in the Y-axis direction, while at the same time irradiating the substrate P with exposure light EL via the projection optical system PL and the liquid LQ in the liquid immersion space LS above the substrate P. By this means, the image of the pattern of the mask M is projected onto the substrate P, and the substrate P is exposed to the exposure light EL.

The illumination system IL illuminates a prescribed illumination region IR on the mask M with exposure light EL with a uniform luminous flux intensity distribution. As the exposure light EL emitted from the illumination system IL, for example, bright lines (g line, h line, i line) emitted from a mercury lamp, deep ultraviolet (DUV) light such KrF excimer laser light (wavelength 248 nm), ArF excimer laser light (wavelength 193 nm), F₂ laser light (wavelength 157 μm), or other vacuum ultraviolet (VUV) light, or similar is used. In this embodiment, ArF excimer laser light, which is ultraviolet light (vacuum ultraviolet light), is used as the exposure light EL.

The mask stage 1 can move, while holding the mask M, by means of a first driving system 1D employing a linear motor or other actuator. The mask stage 1 can move in the XY plane, including positions irradiated by exposure light EL from the illumination system IL. In this embodiment, the position irradiated by exposure light EL from the illumination system IL includes the position of intersection with the optical axis AX of the projection optical system PL. Further, the mask M being held by the mask stage 1 can also move in the XY plane, including the position irradiated by exposure light EL from the illumination system IL. In this embodiment, the mask stage 1 can move in the X-axis, Y-axis, and θZ directions.

The projection optical system PL projects an image of the pattern of the mask M onto the substrate P with a prescribed projection magnification. The plurality of optical elements of the projection optical system PL are held by the lens barrel PK. The projection optical system PL of this embodiment is a reducing system the projection magnification of which is, for example, ¼, ⅕, or ⅛. The projection optical system PL may be a reducing system, an equal-size or enlarging system. In this embodiment, the optical axis AX of the projection optical system PL is parallel to the Z axis. Also, the projection optical system PL may be a refractive system not containing reflecting optical elements, a reflective system not containing refractive optical elements, or a reflective-refractive system containing reflecting optical elements and refracting optical elements. The projection optical system PL may form either an inverted image or a non-inverted image.

The substrate stage 2 can move, while holding the substrate P, by means of a second driving system 2D employing a linear motor or other actuator. The substrate stage 2 moves over the base member 7. The base member 7 has a guide surface 7G which movable supports the substrate stage 2. The guide surface 7G is substantially parallel to the XY plane. The substrate stage 2 can move in the XY plane including positions irradiated with exposure light EL from the terminal optical element 5 (projection optical system PL). In this embodiment, positions irradiated with exposure light EL from the terminal optical element 5 include positions opposing the emission surface 5K of the terminal optical element 5, and include the position intersecting the optical axis of the terminal optical element 5 (the optical axis AX of the projection optical system PL). The substrate P held by the substrate stage 2 can also move in the XY plane including positions irradiated with exposure light EL from the terminal optical element 5 (projection optical system PL). In this embodiment, the substrate stage 2 can move in six directions, which are the X-axis, Y-axis, Z-axis, θX, θY, and θZ directions.

The substrate stage 2 has a substrate holder 2H which holds the substrate P, and an upper surface 2T positioned on the periphery of the substrate holder 2H. The upper surface 2T of the substrate stage 2 is a flat surface substantially parallel to the XY plane.

The substrate holder 2H is positioned in a depression 2C provided on the substrate stage 2. The substrate holder 2H holds the substrate P such that the surface of the substrate P is substantially parallel to the XY plane. The surface of the substrate P held by the substrate holder 2H and the upper surface 2T of the substrate stage 2 are positioned substantially in the same plane, and are substantially flush.

Next, the measurement system 3 is explained. The measurement system 3 measures position information for the mask stage 1 and position information for the substrate stage 2. The measurement system 3 employs a plurality of laser interferometers. The measurement system 3 has a mask stage interferometer system 3M, which measures position information for the mask stage 1, and a substrate stage interferometer system 3P, which measures position information for the substrate stage 2.

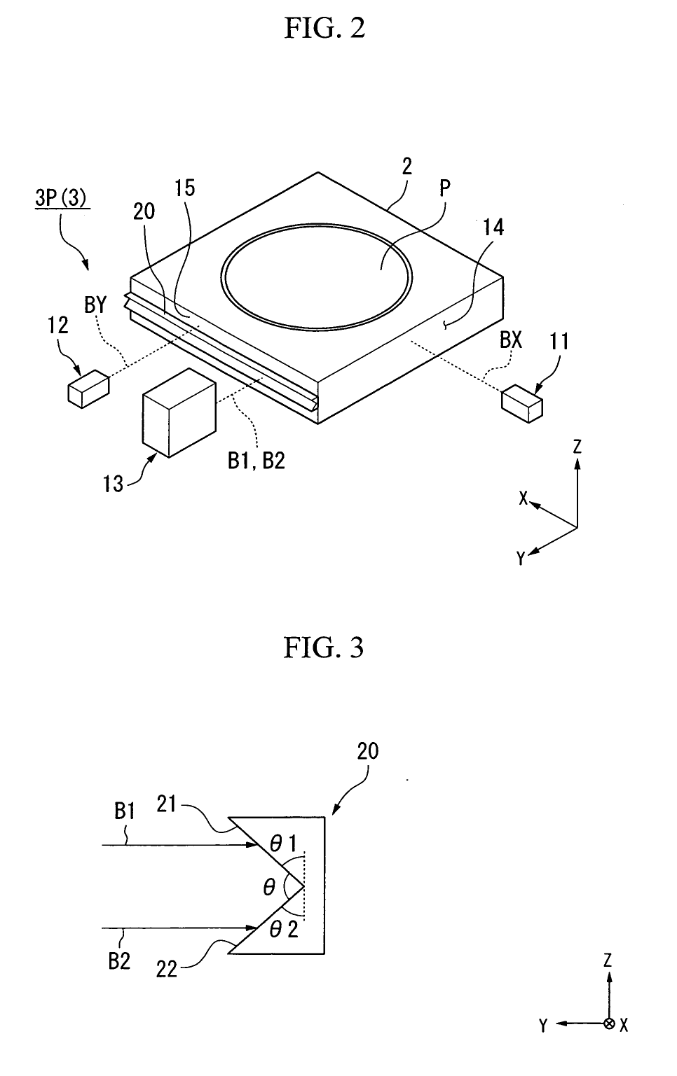

FIG. 2 is a summary perspective view showing the substrate stage 2 and substrate stage interferometer system 3P. The substrate stage interferometer system 3P has an X interferometer system 11, which measures position information for the substrate stage 2 in the X-axis direction; a Y interferometer system 12, which measures position information for the substrate stage 2 in the Y-axis direction; and a Z interferometer system 13, which measures position information for the substrate stage 2 in the Z-axis direction.

The substrate stage 2 employs an X reflecting surface 14, irradiated by a laser beam BX from the X interferometer system 11 to measure position information in the X-axis direction; a Y reflecting surface 15, irradiated by a laser beam BY from the Y interferometer system 12 to measure position information in the Y-axis direction; and an optical member 20, irradiated by a laser beam from the Z interferometer system 13 to measure position information in the Z-axis direction.

The X reflecting surface 14 is a surface perpendicular to the X axis. In other words, the X reflecting surface 14 is a surface parallel to the YZ plane. The X interferometer system 11 uses the X axis as the measurement axis. The laser beam BX from the X interferometer system 11 propagates in the X-axis direction and is incident on the X reflecting surface 14. The X interferometer system 11 receives the laser beam BX reflected by the X reflecting surface 14, and measures position information for the X reflecting surface 14 in the X-axis direction.

The Y reflecting surface 15 is a surface perpendicular to the Y axis. In other words, the Y reflecting surface 15 is a surface parallel to the XZ plane. The Y interferometer system 12 uses the Y axis as the measurement axis. The laser beam BY from the Y interferometer system 12 propagates in the Y-axis direction and is incident on the Y reflecting surface 15. The Y interferometer system 12 receives the laser beam BY reflected by the Y reflecting surface 15, and measures position information for the Y reflecting surface 15 in the Y-axis direction.

The Z interferometer system 13 irradiates the optical member 20 with a laser beam in order to measure position information in the Z-axis direction. The laser beam from the Z interferometer system 13 includes a measurement beam B1 and a measurement beam B2. In this embodiment, the optical member 20 is positioned on the +Y-side side surface of the substrate stage 2.

FIG. 3 is a side view of the optical member 20. The optical member 20 has a first reflecting surface 21, onto which the measurement beam B1 propagating in the Y-axis direction is incident, and a second reflecting surface 22, onto which the reference beam B2 propagating in the Y-axis direction is incident. The first reflecting surface 21 and second reflecting surface 22 are optically connected, and light reflected by one among the first reflecting surface 21 and second reflecting surface 22 is incident on the other.

Specifically, the first reflecting surface 21 is parallel to a plane inclined by a first angle θ1 about the X axis from the XZ plane, containing the X axis and Z axis. The second reflecting surface 22 is parallel to a plane inclined by a second angle θ2 about the X axis from the XZ plane, containing the X axis and Z axis. The angle θ made by the first reflecting surface 21 and second reflecting surface 22 (i.e., angle between the first reflecting surface 21 and second reflecting surface 22) is other than 90°, and is smaller than 180°. In this embodiment, the angle θ is for example other than 90°, and can be for example less than 10, 20, 30, 40, 50, 60, 70, 80, 90, 100, 110, 120, 130, 140, 150, 160, 170, or 180°. Preferably, the angle θ is other than 90°, and can be greater than or equal to 80° and less than or equal to 100, 110, 120, or 130°. More preferably, the angle θ can be greater than or equal to approximately 91° and less than or equal to 100°. For example, the angle θ can be approximately 91, 92, 93, 94, 95, 96, 97, 98, 99, or 100°. The above-described numerical values are merely exemplary; the other numerical values can be used, within the predetermined range.

In the embodiment, the value of θ1 can be the same as the value of θ2. In another embodiment, the value of θ1 can be different from the value of θ2. The value of θ1 and θ2 can be for example less than 5, 10, 15, 20, 25, 30, 35, 40, 45, 50, 55, 60, 65, 70, 75, 80, 85, or 90°. Preferably, this angle can be greater than or equal to 25, 30, 35, or 40°, and less than or equal to 50°. More preferably, the angle can be greater than or equal to approximately 40° and less than or equal to approximately 45°. For example, the angle can be approximately 40, 40.5, 41, 41.5, 42, 42.5, 43, 43.5, 44, 44.5, or 45°. The above-described numerical values are merely exemplary; the other numerical values can be used, within the predetermined range.

In the embodiment, in the successive two-time beam reflections on the optical member 20, the total rotation amount about the X axis can preferably be other than 180°, and can be greater than or equal to 160° and less than or equal to 260°. More preferably, the total rotation amount can be greater than or equal to 182° and less than or equal to 200°. For example, θ can be approximately 182, 184, 186, 188, 190, 192, 194, 196, 198, or 200°. The above-described numerical values are merely exemplary; the other numerical values can be used, within the predetermined range.

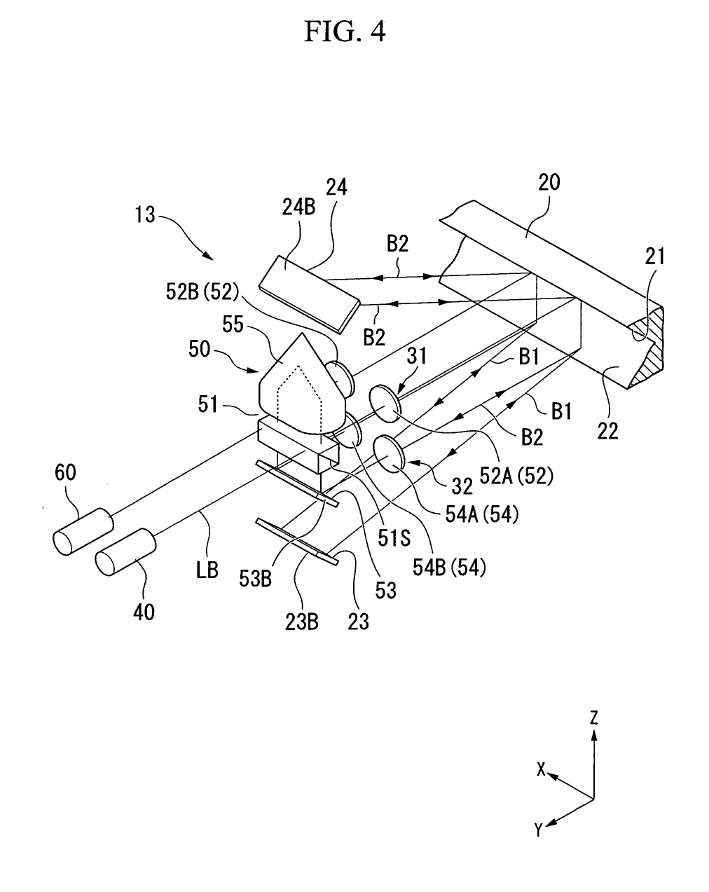

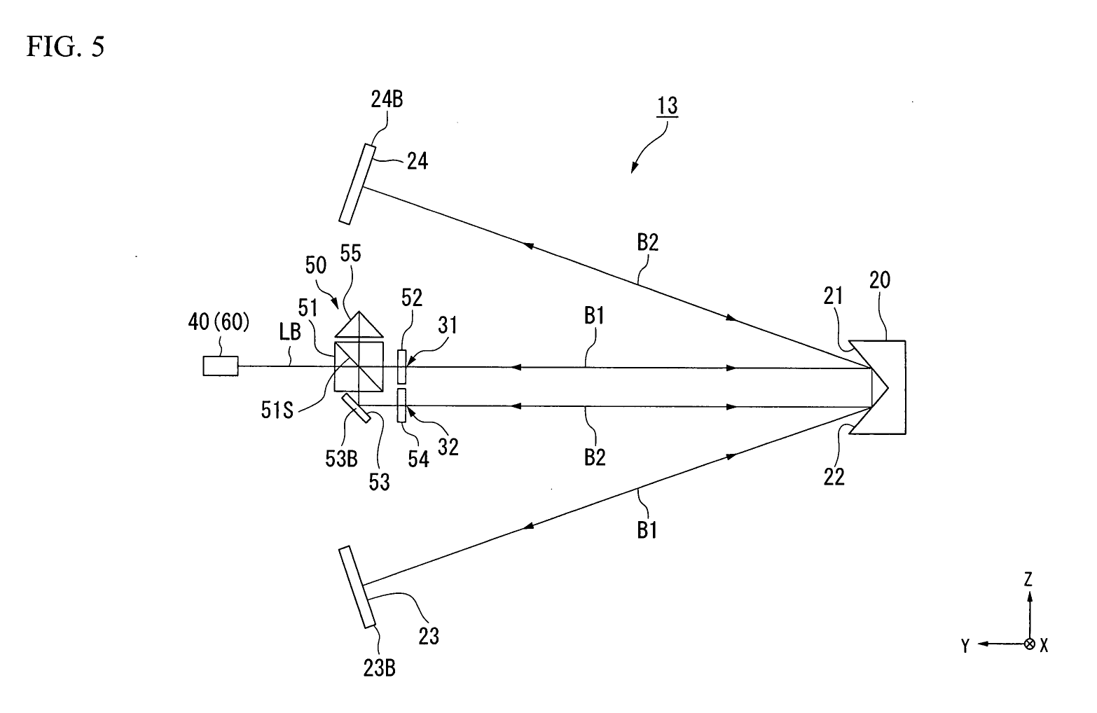

FIG. 4 is a summary perspective view of the Z interferometer system 13, and FIG. 5 is a summary configuration diagram showing the Z interferometer system 13. In FIG. 4 and FIG. 5, the Z interferometer system 13 has a first emission portion 31, which emits a measurement beam B1; a second emission portion 32, which emits a reference beam B2; a third reflecting surface 23, optically connected to the second reflecting surface 22 of the optical member 20, at a first position, and which is substantially stationary; and a fourth reflecting surface 24, optically connected to the first reflecting surface 21 of the optical member 20, at a second position, and which is substantially stationary. The first position includes positions on the −Z side of the optical member 20, opposing the first reflecting surface 21. The second position includes positions on the +Z side of the optical member 20, opposing the second reflecting surface 22. In other words, the third reflecting surface 23 and the fourth reflecting surface 24 are separately located adjacent to the both sides of the XY plane, which includes an optical central position along the Z axis of the optical member 20. The Z interferometer system 31 irradiates the optical member 20 with the measurement beam B1 and reference beam B2, receives the measurement beam B1 and reference beam B2 from the optical member 20, and acquires interference information based on the measurement beam B1 and reference beam B2.

The measurement beam B1 emitted from the first emission portion 31 propagates in the Y-axis direction (−Y direction) and is incident on the first reflecting surface 21 of the optical member 20. The reference beam B2 emitted from the second emission portion 32 propagates in the Y-axis direction (−Y direction) and is incident on the second reflecting surface 22 of the optical member 20.

The third reflecting surface 23 is positioned at the first position, so as to be substantially stationary. In this embodiment, the third reflecting surface 23 is positioned on a fixed member 23B fixed to a prescribed support mechanism so as to be substantially stationary.

The third reflecting surface 23 is parallel to a plane inclined by a prescribed angle about the X axis from the XZ plane, which includes the X axis and Z axis. The third reflecting surface 23 opposes the first reflecting surface 21, and is optically connected to the second reflecting surface 22.

The fourth reflecting surface 24 is positioned at the second position, so as to be substantially stationary. In this embodiment, the fourth reflecting surface 24 is positioned on a fixed member 24B fixed to a prescribed support mechanism so as to be substantially stationary.

The fourth reflecting surface 24 is parallel to a plane inclined by a prescribed angle about the X axis from the XZ plane, which includes the X axis and Z axis. The fourth reflecting surface 24 opposes the second reflecting surface 22, and is optically connected to the first reflecting surface 21.

In this embodiment, the Z interferometer system 13 is a so-called double-path type laser interferometer system, and has a light source 40, which emits a laser beam LB; an optical system 50, which causes the measurement beam B1 to make at least two complete round trips to the third reflecting surface 23, and which causes the reference beam B2 to make at least two complete round trips to the fourth reflecting surface 24; and a photodetector 60.

The optical system 50 has a polarizing beam splitter 51, which splits the laser beam LB emitted from the light source 40 into the measurement beam B1 and the reference beam B2; a λ/4 plate 52 (52A, 52B), placed in the optical path between the polarizing beam splitter 51 and the first reflecting surface 21; a λ/4 plate 54 (54A, 54B), placed in the optical path between the polarizing beam splitter 51 and the second reflecting surface 22; a corner cube 55, placed on the +Z side of the polarizing beam splitter 51; and a reflecting mirror 53B, having a reflecting surface 53 positioned on the −Z side of the polarizing beam splitter 51.

The laser beam LB emitted from the light source 40 is incident on the polarizing beam splitter 51. The polarizing beam splitter 51 has a polarizing separation surface 51S which separates the incident laser beam LB into a measurement beam B1 in a first polarization state and a reference beam B2 in a second polarization state. The laser beam LB emitted from the light source 40 and incident on the polarizing beam splitter 51 is split into the measurement beam B1 in the first polarization state and the reference beam B2 in the second polarization state. The reference beam B2 is reflected by the polarizing separation surface 51S and is emitted from the surface on the −Z side of the polarizing beam splitter 51. The measurement beam B1 passes through the polarizing separation surface 51S, and is emitted from the surface on the −Y side of the polarizing beam splitter 51. In the following explanation, an example is explained in which the polarizing beam splitter 51 (polarizing separation surface 51S) splits a laser beam LB from the light source 40 into a measurement beam B1 in the P polarization state and a reference beam B2 in the S polarization state.

After passing through the polarizing separation surface 51S, the measurement beam B1 in the P polarization state, propagating in the −Y direction, passes through the λ/4 plate 52 (52A), and after being converted into circularly-polarized light, irradiates the first reflecting surface 21.

Upon irradiating the first reflecting surface 21, and after being reflected by the first reflecting surface 21, the measurement beam B1 is incident on the second reflecting surface 22. After being incident on the second reflecting surface 22, and after being reflected by the second reflecting surface 22, the measurement beam B1 is incident on the third reflecting surface 23.

The third reflecting surface 23 is planar, and the measurement beam B1 from the second reflecting surface 22 is incident substantially perpendicularly onto the third reflecting surface 23. The measurement beam B1, upon being incident on the third reflecting surface 23, is reflected by the third reflecting surface 23, and is incident on the second reflecting surface 22. Upon irradiating the second reflecting surface 22 and being reflected by the second reflecting surface 22, the measurement beam B1 is incident on the first reflecting surface 21. Upon being incident on the first reflecting surface 21 and being reflected by the first reflecting surface 21, the measurement beam B1 propagates in the +Y direction, again passes through the λ/4 plate 52 (52A), and after being converted into S-polarized light, is again incident on the polarizing beam splitter 51 from the surface on the −Y side of the polarizing beam splitter 51.

The measurement beam B1 in the S-polarized state, having again been incident on the polarizing beam splitter 51, is reflected by the polarizing separation surface 51S, propagates in the +Z direction, is emitted from the surface on the +Z side of the polarizing beam splitter 51, and is incident on the corner cube 55. The measurement beam B1, upon incidence on the corner cube 55, propagates in the +X direction within the corner cube 55, and then propagates in the −Z direction, and is emitted from the surface on the −Z side of the corner cube 55. Upon being emitted from the surface on the −Z side of the corner cube 55, the measurement beam B1 is incident on the surface on the +Z side of the polarizing beam splitter 51, and after being reflected by the polarizing separation surface 51S, propagates in the −Y direction, and is emitted from the surface on the −Y side of the polarizing beam splitter 51. After being reflected by the polarizing separation surface 51S and propagating in the −Y direction, the measurement beam B1 in the S-polarized state passes through the λ/4 plate 52 (52B), and after being converted into circularly polarized light, irradiates the first reflecting surface 21.

Upon irradiating the first reflecting surface 21, the measurement beam B1 is reflected by the first reflecting surface 21 and is incident on the second reflecting surface 22. After incidence on the second reflecting surface 22, the measurement beam B1 is reflected by the second reflecting surface 22 and is incident on the third reflecting surface 23. After incidence on the third reflecting surface 23, the measurement beam B1 is reflected by the third reflecting surface 23, and is incident on the second reflecting surface 22. After irradiating the second reflecting surface 22, the measurement beam B1 is reflected by the second reflecting surface 22, and is incident on the first reflecting surface 21. After incidence on the first reflecting surface 21, the measurement beam B1 is reflected by the first reflecting beam 21, propagates in the +Y direction, again passes through the λ/4 plate 52 (52B), and after being converted into light in the P-polarized state, is again incident on the polarizing beam splitter 51 from the surface on the −Y side of the polarizing beam splitter 51.

Upon again being incident on the polarizing beam splitter 51, the measurement beam B1 in the P-polarized state passes through the polarizing separation surface 51S, is emitted from the surface on the +Y side, and is incident on the photodetector 60.

On the other hand, the reference beam B2 in the S-polarized state, having been emitted from the light source 40 and reflected by the polarizing separation surface 51S, propagates in the −Z direction, is emitted from the surface on the −Z side of the polarizing beam splitter 51, is reflected by the reflecting surface 53, propagates in the −Y direction, and is incident on the λ/4 plate 54 (54A). The reference beam B2 in the S-polarized state, propagating in the −Y direction, passes through the λ/4 plate 54 (54A), and after being converted into circularly-polarized light, irradiates the second reflecting surface 22.

Upon irradiating the second reflecting surface 22, the reference beam B2 is reflected by the second reflecting surface 22, and is incident on the first reflecting surface 21. Upon being incident on the first reflecting surface 21, the reference beam B2 is reflected by the first reflecting surface 21, and is incident on the fourth reflecting surface 24.

The fourth reflecting surface 24 is a flat surface, and the reference beam B2 from the first reflecting surface 21 is incident substantially perpendicularly on the fourth reflecting surface 24. After being incident on the fourth reflecting surface 24, the reference beam B2 is reflected by the fourth reflecting surface 24, and is incident on the first reflecting surface 21. After irradiating the first reflecting surface 21, the reference beam B2 is reflected by the first reflecting surface 21, and is incident on the second reflecting surface 22. After being incident on the second reflecting surface 22, the reference beam B2 is reflected by the second reflecting surface 22, propagates in the +Y direction, again passes through the λ/4 plate 54 (54A), and after being converted into light in the P-polarized state, and being reflected by the reflecting surface 53, is again incident on the polarizing beam splitter 51 from the surface on the −Z side of the polarizing beam splitter 51.

After again being incident on the polarizing beam splitter 51, the reference beam B2 in the P-polarized state passes through the polarizing separation surface 51S, propagates in the +Z direction, is emitted from the surface on the +Z side of the polarizing beam splitter 51, and is incident on the corner cube 55. Upon being incident on the corner cube 55, the reference beam B2 propagates in the +X direction within the corner cube 55, then propagates in the −Z direction, and is emitted from the surface on the −Z side of the corner cube 55. Upon being emitted from the surface on the −Z side of the corner cube 55, the reference beam B2 is incident on the surface on the +Z side of the polarizing beam splitter 51, and after passing through the polarizing separation surface 51S, is emitted from the surface on the −Z side of the polarizing beam splitter 51. After passing through the polarizing separation surface 51S and propagating in the −Z direction, the reference beam B2 in the P-polarized state is reflected by the reflecting surface 53, and propagates in the −Y direction. The reference beam B2, propagating in the −Y direction, passes through the λ/4 plate 54 (54B), and after being converted into circularly-polarized light, irradiates the second reflecting surface 22.

Upon irradiating the second reflecting surface 22, the reference beam B2 is reflected by the second reflecting surface 22, and is incident on the first reflecting surface 21. Upon being incident on the first reflecting surface 21, the reference beam B2 is reflected by the first reflecting surface 21, and is incident on the fourth reflecting surface 24. Upon being incident on the fourth reflecting surface 24, the reference beam B2 is reflected by the fourth reflecting surface 24, and is incident on the first reflecting surface 21. Upon irradiating the first reflecting surface 21, the reference beam B2 is reflected by the first reflecting surface 21, and is incident on the second reflecting surface 22. Upon being incident on the second reflecting surface 22, the reference beam B2 is reflected by the second reflecting surface 22, propagates in the +Y direction, again passes through the λ/4 plate 54 (54B), and after being converted into light in the S-polarized state, is reflected by the reflecting surface 53, and is again incident on the polarizing beam splitter 51 from the surface on the −Z side of the polarizing beam splitter 51.

Upon again being incident on the polarizing beam splitter 51, the reference beam B2 in the S-polarized state is reflected by the polarizing separation surface 51S, is emitted from the surface on the +Y side, and is incident on the photodetector 60.

The photodetector 60 receives the measurement beam B1 and reference beam B2 from the polarizing beam splitter 51. The Z interferometer system 13 measures position information for the substrate stage 2 (optical member 20) in the Z-axis direction, based on the measurement beam B1 and reference beam B2 incident on the photodetector 60. When the position of the substrate stage 2 (optical member 20) in the Z-axis direction changes, the optical path lengths of the measurement beam B1 and reference beam B2 change. The Z interferometer system 13 measures the position information of the substrate stage 2 (optical member 20) in the Z-axis direction based on these changes in optical path lengths.

When the substrate P is exposed, the control apparatus 4 uses the measurement system 3, and while measuring position information for the mask stage 1 and substrate stage 2, moves the mask M and substrate P while exposing shot regions on the substrate P. The control apparatus 4 drives the first driving system 1D based on measurement results of the mask stage interferometer system 3M, and performs position control of the mask M being held by the mask stage 1, while also driving the second driving system 2D based on measurement results of the substrate stage interferometer system 3P, and while performing position control of the substrate P being held by the substrate stage 2, exposes the substrate P.

As explained above, by means of this embodiment the Z interferometer system 13 and optical member 20 can be used to measure position information for the substrate stage 2 in the Z-axis direction. Also, by means of this embodiment, increases in the size of the optical member 20 are suppressed.

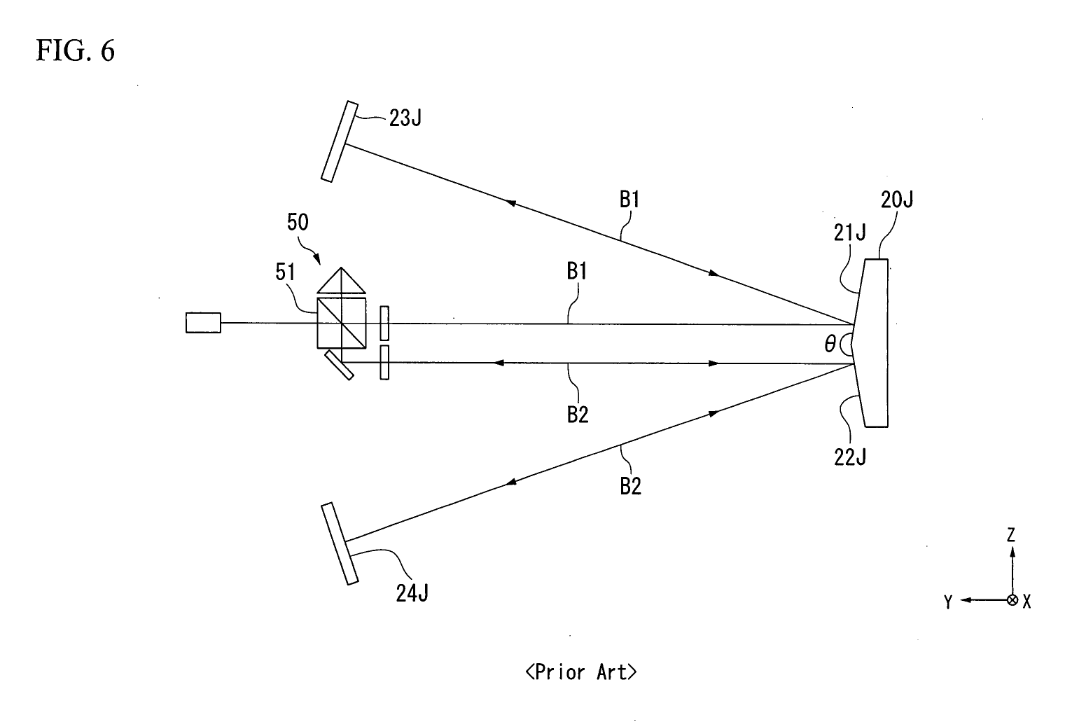

FIG. 6 shows a comparison example. In FIG. 6, the angle θ made by the first reflecting surface 21J and the second reflecting surface 22J of the optical member 20J is larger than 180°. In the example shown in FIG. 6 also, an optical system 50 is provided, and the measurement beam B1 and reference beam B2 make round trips to and from the optical member 20J. In the example shown in FIG. 6, when for example the substrate stage 2 (optical member 20J) rotates in the θX direction, there is the possibility that the position of the measurement beam B1 upon the second irradiation of the first reflecting surface 21J has changed greatly relative to the position of the measurement beam B1 upon the first irradiation. Similarly, when the substrate stage 2 (optical member 20J) rotates in the θX direction, there is the possibility that the position of the reference beam B2 upon the second irradiation of the second reflecting surface 22J has changed greatly relative to the position of the reference beam B2 upon the first irradiation. In this case, the optical member 20J must be increased in size, in order that the measurement beam B1 and reference beam B2 may be satisfactorily reflected at the first reflecting surface 21J and second reflecting surface 22J. In this case the mass of the substrate stage 2 may be increased, the acceleration performance of the substrate stage 2 may be diminished, and the load on the second driving system 2D may be increased. Further, it may be necessary to increase the size of the optical system 50 employing the polarizing beam splitter 51 and other components.

In this embodiment, a so-called roof-type optical member 20, in which the angle θ made by the first reflecting surface 21 and the second reflecting surface 22 is smaller than 180°, is used, so that position measurement of the optical member 20 (substrate stage 2) can be executed satisfactorily, while keeping the optical member 20 small.

Further, in this embodiment the Z interferometer system 13 is the so-called double-path type, and a corner cube 55 is used to shift the incident measurement beam B1 and reference beam B2 in the X-axis direction. By adopting a double-path design, large shifts of the measurement beam B1 and reference beam B2 in the X-axis direction can be suppressed, and the Z interferometer system 13 can be kept small.

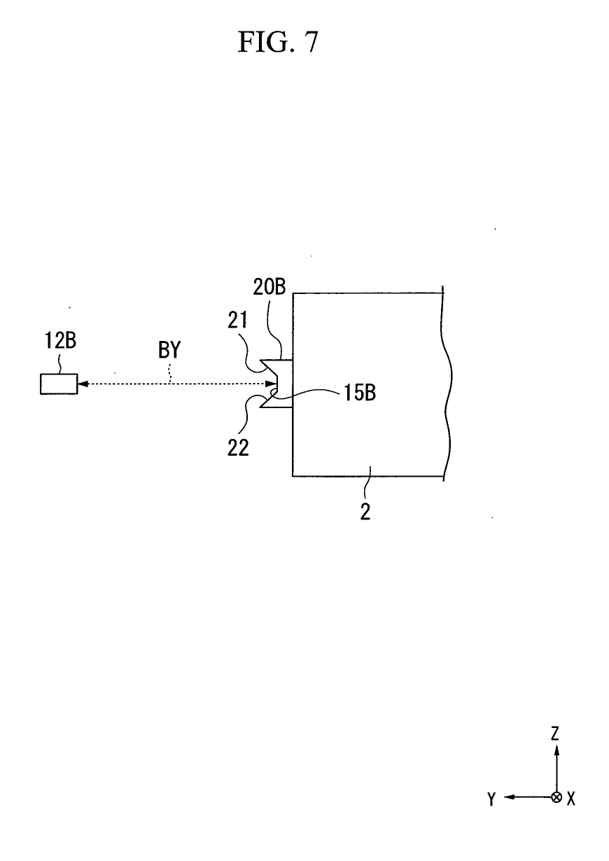

As shown in FIG. 7, the optical member 20B may have a first reflecting surface 21, second reflecting surface 22, and a reflecting surface 15B perpendicular to the Y axis (in the XZ plane). By using such an optical member 20B, the Y interferometer system 12B can use the Y reflecting surface 15B of the optical member 20B to execute position measurements in the Y-axis direction. A reflecting surface separate from the optical member 20B may be provided on the substrate stage 2, and based on corresponding position information in the Y-axis direction obtained using the Y interferometer system and on the measurement results obtained from the reflecting surface 15B and the corresponding Y interferometer system 12B, displacement of the substrate stage 2 in the θX direction may be measured. The Z interferometer system 13 can execute position measurement processing using the first reflecting surface 21 and second reflecting surface 22 of the optical member 20B. Also, by positioning the optical member 20B such that the reflecting surface 15B is perpendicular to the X axis, position measurements in the X-axis direction can be executed.

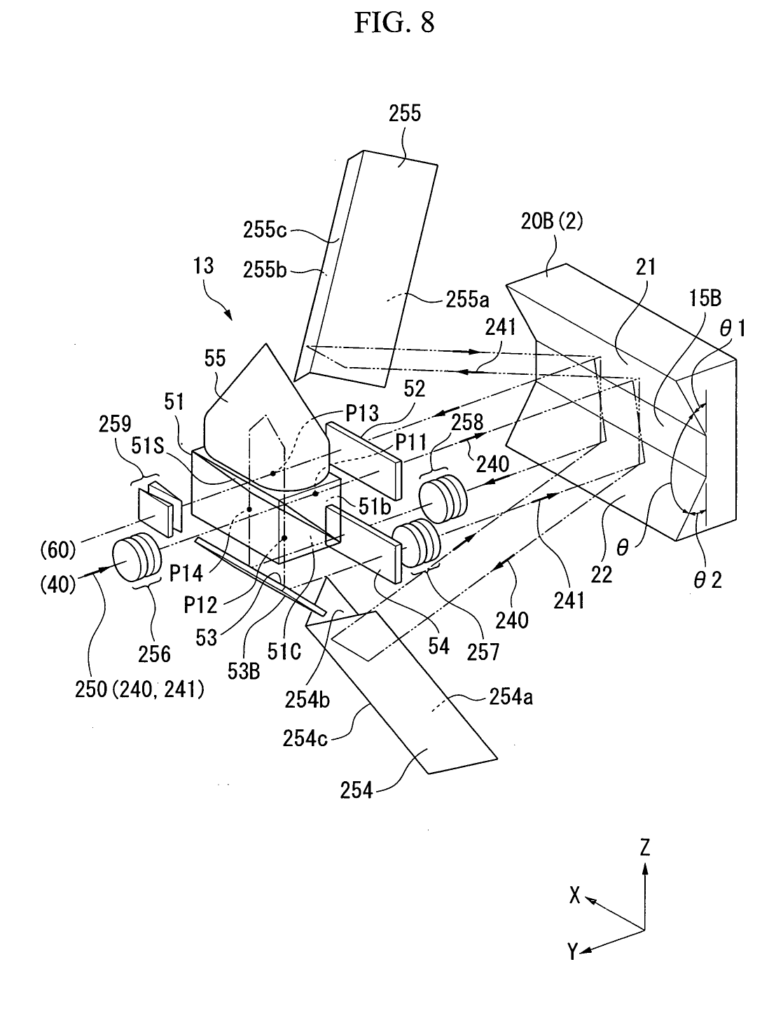

FIG. 8 is a schematic perspective view showing the Z interferometer system 13 with the optical member 20B as shown in FIG. 7.

In the embodiment, as shown in FIG. 8, the Z interferometer system 13 comprises the polarizing beam splitter 51, the λ/4 plates 52, 54, the reflecting mirror 53B, the corner cube 55, the optical member 20B, which serves as a moving mirror, and roof mirrors 254, 255, which serve as fixed mirrors, and further comprises, as needed, adjusting mechanisms 256, 257, 258, 259 in order to adjust the optical axis of the beam.

In the embodiment, each of the adjusting mechanisms 256, 257, 258 includes two optical elements in face-to-face arrangement, and a retainer (not shown in figure) that holds and retains each of the optical elements. In each of the adjusting mechanisms 256, 257, 258, the relative position (e.g., rotational position about the optical axis) between the two optical elements (e.g., deviation lens) can be changed to adjust the optical axis of the beam. The adjusting mechanism 259 has an aspect, which is similar to or different from that of the adjusting mechanism 256, 257, 258. For example, the adjusting mechanism 259 can have at least one of a shift function of optical axis, and a reducing function. Furthermore, the configuration, the number, and the arrangement position of the adjusting mechanism are not limited to the example as shown in FIG. 8.

A laser beam 250 from the light source 40 includes a pair of polarization components, which have stabilized wavelength respectively, and the polarization directions thereof are perpendicular to each other. In the following explanation, an example is explained in which the polarizing beam splitter 51 (polarizing separation surface 51S) splits the laser beam 250 from the light source 40 into a reference beam 240 in the P polarization state and a measurement beam 241 in the S polarization state. Alternatively, the opposite relationship thereof can be applied.

In the Z interferometer system 13, the reference beam 240 and the measurement beam 241 can be directed onto the optical member 20B, and the interference information can be acquired based on the reception result of the reference beam 240 and the measurement beam 241 from the optical member 20B.

In the embodiment, as needed, an adjusting mechanism 256 is arranged on the optical path of the laser beam 250 between the light source 40 and the polarizing beam splitter 51 to adjust the optical axis of the laser beam 250. The adjusting mechanism 256 can be used, for example, for adjusting degree of perpendicularity of the reference beam 240, and the like.

The laser beam 250 travels along the −Y direction within the XY plane and is incident on the polarizing separation surface 51S of the polarizing beam splitter 51 and is split at the polarizing separation surface 51S into the frequency components, which are perpendicular to each other, of two frequency components (P polarization component and S polarization component).

The reference beam (P polarization component) 240 is transmitted through the polarizing separation surface 51S of the polarizing beam splitter 51, and travels along the −Y direction, and then exits from a first surface 51b at an exit position P11. The measurement beam (S polarization component) 241 is reflected and bent at the polarizing separation surface 51S of the polarizing beam splitter 51, and travels along the −Z direction, and then exits from a second surface 51c at an exit position P12.

The reference beam 240 from the polarizing beam splitter 51 is converted into circularly-polarized light at the λ/4 plate 52, and then is directed onto the first reflecting surface 21 of the optical member 20B. The measurement beam 241 form the polarizing beam splitter 51 is bent by means of the reflecting surface 53 of the reflecting mirror 53B, and then travels along the −Y direction. On the optical path of the measurement beam 241 between the reflecting mirror 53B and the optical member 20B, as needed, there is provided with the adjusting mechanism 257, and the optical axis of the measurement beam 241 is adjusted. The adjusting mechanism 257 can be used, for example, for adjusting degree of perpendicularity of the measurement beam 241, and the like. The reference beam 241 from the reflecting mirror 53B is converted into circularly-polarized light at the λ/4 plate 54, and is transmitted through the adjusting mechanism 257, and then is directed onto the second reflecting surface 22 of the optical member 20B. In the embodiment, the λ/4 plates 52, 54 can be disposed apart from the polarizing beam splitter 51, or can be disposed in contact with the polarizing beam splitter 51.

In the embodiment, the optical member 20B has the reflecting surface 15B; the first reflecting surface 21, which is disposed parallel to the X axis and inclined from the XZ plane; and the second reflecting surface 22, which is disposed parallel to the X axis and inclined from the XZ plane in the opposite direction to that of the first reflecting surface 21. The first reflecting surface 21 is optically connected to the second reflecting surface 22, and light reflected by one among the first reflecting surface 21 and the second reflecting surface 22 is incident on the other reflecting surface. In the embodiment, on the first reflecting surface 21 and on the second reflecting surface 22, the incident beam into the optical member 20B is reflected successively twice.

Specifically, the first reflecting surface 21 is parallel to a plane inclined by a first angle θ1 about the X axis from the XZ plane, containing the X axis and Z axis. The second reflecting surface 22 is parallel to a plane inclined by a second angle θ2 about the X axis in the opposite direction to that of the first reflecting surface 21, from the XZ plane containing the X axis and Z axis. The angle θ made by the first reflecting surface 21 and second reflecting surface 22 (i.e., angle between the first reflecting surface 21 and second reflecting surface 22) is other than 90°, and is smaller than 180°. In this embodiment, the angle θ is for example other than 90°, and can be for example less than 10, 20, 30, 40, 50, 60, 70, 80, 90, 100, 110, 120, 130, 140, 150, 160, 170, or 180°. Preferably, the angle θ is other than 90°, and can be greater than or equal to 80° and less than or equal to 100, 110, 120, or 130°. More preferably, the angle θ can be greater than or equal to approximately 91° and less than or equal to 100°. For example, the angle θ can be approximately 91, 92, 93, 94, 95, 96, 97, 98, 99, or 100°. The above-described numerical values are merely exemplary; the other numerical values can be used, within the predetermined range.

In the embodiment, the value of θ1 can be the same as the value of θ2. In another embodiment, the value of θ1 can be different from the value of θ2. The value of θ1 and θ2 can be for example less than 5, 10, 15, 20, 25, 30, 35, 40, 45, 50, 55, 60, 65, 70, 75, 80, 85, or 90°. Preferably, this angle can be greater than or equal to 25, 30, 35, or 40°, and less than or equal to 50°. More preferably, the angle can be greater than or equal to approximately 40° and less than or equal to approximately 45°. For example, the angle can be approximately 40, 40.5, 41, 41.5, 42, 42.5, 43, 43.5, 44, 44.5, or 45°. The above-described numerical values are merely exemplary; the other numerical values can be used, within the predetermined range.

In the embodiment, in the successive two-time reflection on the optical member 20B, the total rotation amount about the X axis can preferably be other than 180°, and can be greater than or equal to 160° and less than or equal to 260°. More preferably, the total rotation amount can be greater than or equal to 182° and less than or equal to 200°. For example, θ can be approximately 182, 184, 186, 188, 190, 192, 194, 196, 198, or 200°. The above-described numerical values are merely exemplary; the other numerical values can be used, within the predetermined range.

The incident beam 240 into the optical member 20B is reflected on the first reflecting surface 21 and on the second reflecting surface 22. That is, the route of the reference beam 240 comprises the successive two-time reflection on the optical member 20B, in which the reference beam 240 is bent about the X axis. The reference beam 240 from the second reflecting surface 22 of the optical member 20B is incident onto the roof mirror 254. On the other hand, the incident measurement beam 241 into the optical member 20B is reflected on the second reflecting surface 22 and the first reflecting surface 21. That is, the route of the measurement beam 241 comprises the successive two-time reflection on the optical member 20B, in which the measurement beam 241 is bent about the X axis. The measurement beam 241 from the first reflecting surface 21 of the optical member 20B is incident onto the roof mirror 255.

In the embodiment, the roof mirrors 254, 255 are fixed to the main body of the exposure apparatus EX (refer to FIG. 1) so as to be substantially stationary. In the embodiment, the roof mirror 254 is disposed apart from (in the −Z direction) and below the polarizing beam splitter 51, and the roof mirror 255 is disposed apart from (in the +Z direction) and above the polarizing beam splitter 51. In other words, the roof mirror 254 and the roof mirror 255 are separately located with the XY plane therebetween and next to the both sides of the XY plane, which includes an optical central position along the Z axis of the optical member 20B. The roof mirror 254 has two reflecting surfaces 254a, 254b, which make an angle of 90 degrees. The roof mirror 255 has two reflecting surfaces 255a, 255b, which make an angle of 90 degrees. An intersection line 254c of the reflecting surfaces 254a, 254b and an intersection line 255c of the reflecting surface 255a, 255b can lie within the YZ plane and can be perpendicular to the travel direction of the beam from the optical member 20B. Furthermore, attendant with the movement of the substrate stage 2 (refer to FIG. 7) along the Z axis as well as along the Y axis, the irradiation position of the beam with respect to the roof mirror 254 (255) changes in the direction along the intersection line 254c (255c). The length to which each of the roof mirrors 254, 255 extends in the intersection line direction of the roof mirrors 254, 255 is determined based on the range of motion of the substrate stage 2 along the Y axis.

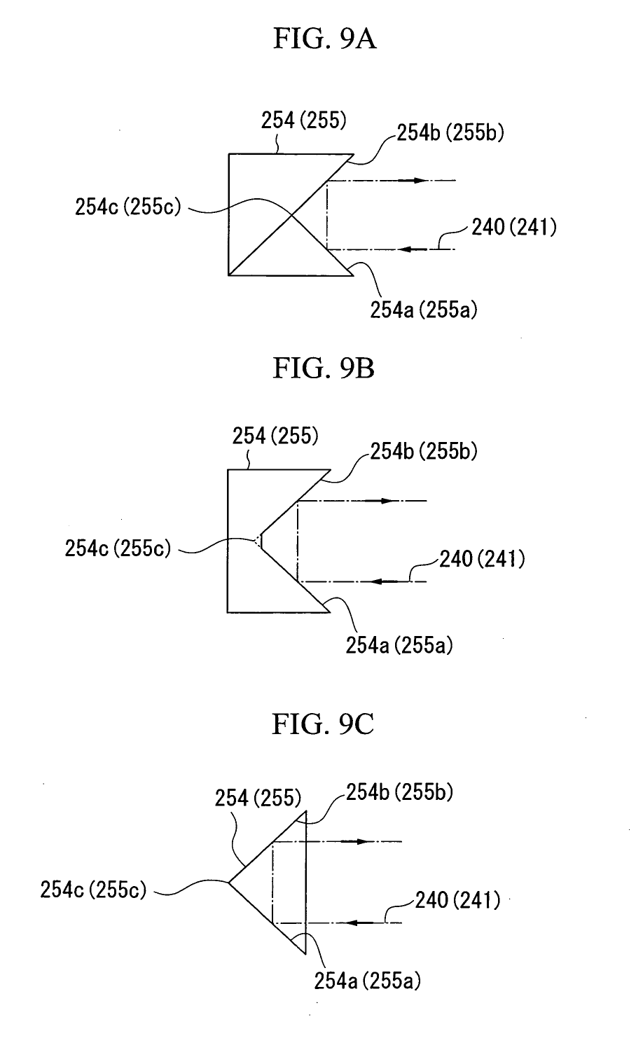

FIG. 9A, FIG. 9B, and FIG. 9C show embodiments of the roof mirrors 254, 255.

In FIG. 9A, the roof mirror 254 (255) comprises a combination of two mirrors. The reflecting surfaces 254a, 254b (255a, 255b) of the mirror form a narrow angle of 90°. The two mirrors can be combined with each other. Each of the mirrors can be fixed to a support body (not shown) by, for example, an adhesive or a metal spring. Alternatively, the two mirrors can be separated; in this case, the intersection line 254c (255c) of the two reflecting surfaces 254a, 254b (255a, 255b) becomes a virtual line. The configuration of each of the mirrors is not limited to the example as shown in FIG. 9A.

In FIG. 9B, the roof mirror 254 (255) has an integrated structure. As shown in FIG. 9B, the two reflecting surfaces 254a, 254b (255a, 255b), which mutually form a narrow angle of 90°, are formed on the roof mirror 254A (255).

In FIG. 9C, the roof mirror 254 (255) has a roof prism structure. The two reflecting surfaces 254a, 254b (255a, 255b), which mutually form a narrow angle of 90°, are formed on the roof prism. Glass or quartz glass is used as the forming material of the roof prism, and it is preferable to use a material with a low relative index of refraction and a low rate of change in temperature.

Returning to FIG. 8, the reference beam 240 that impinged upon the roof mirror 254 is retroreflected attendant with the shift in the optical axis, and then returns from the roof mirror 254 to the optical member 20B. Specifically, the reference beam 240 from the optical member 20B is bent 90° by the reflecting surface 254a of the roof mirror 254, proceeds in the +X direction, and then impinges upon the reflecting surface 254b. The reference beam 240 is bent 90° by the reflecting surface 254b, and proceeds diagonally upward in the −Y direction toward the optical member 20B. Namely, the route of the reference beam 240 comprises the successive two-time reflection on the roof mirror 254. In this successive twice reflections, the total rotation amount about the Z axis is approximately 180°. The reference beam 240 that impinges upon the roof mirror 254 and the reference beam 240 that emerges from the roof mirror 254 are substantially parallel, and the optical axis of the emergent beam is shifted in the +X direction parallel to the optical axis of the incident beam. Namely, the roof mirror 254 shifts the optical axis (optical path) of the reference beam 240 in the +X direction, which is a direction orthogonal to the intersection line 254c of the two reflecting surfaces 254a, 254b.

The reference beam 240 from the roof mirror 254 is reflected by the second reflecting surface 22 and the first reflecting surface 21 of the optical member 20B. Namely, the route of the reference beam 240 further comprises another successive two-time reflection on the optical member 20B, in which the reference beam 240 is bent about the X axis. The reference beam 240 from the optical member 20B proceeds toward the λ/4 plate 52 and the polarizing beam splitter 51 in the +Y direction. Furthermore, the reference beam passes through the λ/4 plate 52, and is thereby converted to S polarized state light that has a polarized light direction that is orthogonal to the original polarized light direction. The converted reference beam 240 enters the polarizing beam splitter 51, at an incident position P13 on the first surface 51b. The incident reference beam 240 is reflected by the polarizing separation surface 51S of the polarizing beam splitter 51, and then enters the corner cube (corner cube retro reflector) 55.

The reference beam 240 returns from the corner cube 55 to the polarizing beam splitter 51 via reflection that is attendant with a shift in the optical axis along the X axis. The reference beam 240 that impinges upon the corner cube 55 and the reference beam 240 that emerges from the corner cube 55 are mutually parallel, and the optical axis of the emergent beam is shifted in the −X direction parallel to the optical axis of the incident beam.

The reference beam 240 from the corner cube 55 is reflected by the polarizing separation surface 51S of the polarizing beam splitter 51, and proceeds in the −Y direction, and then emerges from the first surface 51b of the polarizing beam splitter 51. In the second round, the exit position P11 of the reference beam 240 on the first surface 51b of the polarizing beam splitter 51 is substantially the same as that of the first round. In the second round, the reference beam 240 from the polarizing beam splitter 51 travels along the same route of the reference beam 240 in the first round (the λ/4 plate 52, the optical member 20B, the roof mirror 254, the optical member 20B, and the λ/4 plate 52), and then returns to the polarizing beam splitter 51. In the second round, the reference beam 240 from the optical member 20B enters the λ/4 plate 52, passes therethrough, and is thereby converted to P polarized state light that has a polarized light direction that is the same as the original polarized light direction. And then, the reference beam 240 is transmitted through the polarizing beam splitter 51, further proceeds in the +Y direction, and enters the photodetector 60.

On the other hand, the measurement beam 241 that impinged upon the roof mirror 255 is retroreflected attendant with the shift in the optical axis, and then returns from the roof mirror 255 to the optical member 20B. Specifically, the measurement beam 241 from the optical member 20B is bent 90° by the reflecting surface 255a of the roof mirror 255, proceeds in the +X direction, and then impinges upon the reflecting surface 255b. The measurement beam 241 is bent 90° by the reflecting surface 255b, and proceeds diagonally downward in the −Y direction toward the optical member 20B. Namely, the route of the measurement beam 241 comprises the successive two-time reflection on the roof mirror 255. In this successive twice reflections, the total rotation amount about the Z axis is approximately 180°. The measurement beam 241 that impinges upon the roof mirror 255 and the measurement beam 241 that emerges from the roof mirror 255 are substantially parallel, and the optical axis of the emergent beam is shifted in the +X direction parallel to the optical axis of the incident beam. Namely, the roof mirror 255 shifts the optical axis (optical path) of the measurement beam 241 in the +X direction, which is a direction orthogonal to the intersection line 255c of the two reflecting surfaces 255a, 255b.

The measurement beam 241 from the roof mirror 255 is reflected by the first reflecting surface 21 and the second reflecting surface 22 of the optical member 20B. Namely, the route of the measurement beam 241 further comprises another successive two-time reflection on the optical member 20B, in which the measurement beam 241 is bent about the X axis. The measurement beam from the optical member 20B proceeds toward the λ/4 plate 54 and the polarizing beam splitter 51 in the +Y direction. On the optical path of the measurement beam 241 between the optical member 20B and the λ/4 plate 54, as needed, there is provided with the adjusting mechanism 258, and the optical axis of the measurement beam 241 is adjusted. The adjusting mechanism 258 can be used, for example, for alignment of the measurement beam 241, and the like. Furthermore, the measurement beam 241 passes through the λ/4 plate 54, and is thereby converted to P polarized state light that has a polarized light direction that is orthogonal to the original polarized light direction. The converted measurement beam 241 is reflected by the reflecting mirror 53B, and enters the polarizing beam splitter 51, at an incident position P14 on the second surface 51c. The incident measurement beam 241 is transmitted through the polarizing separation surface 51S of the polarizing beam splitter 51, and then enters the corner cube 55.

The measurement beam 241 returns from the corner cube 55 to the polarizing beam splitter 51 via reflection that is attendant with a shift in the optical axis along the X axis. The measurement beam 241 that impinges upon the corner cube 55 and the measurement beam 241 that emerges from the corner cube 55 are substantially parallel, and the optical axis of the emergent beam is shifted in the −X direction parallel to the optical axis of the incident beam.

The measurement beam 241 from the corner cube 55 is transmitted through the polarizing separation surface 51S of the polarizing beam splitter 51, and then emerges from the second surface 51c of the polarizing beam splitter 51. In the second round, the exit position P12 of the measurement beam 241 on the second surface 51c of the polarizing beam splitter 51 is substantially the same as that of the first round. In the second round, the measurement beam 241 from the polarizing beam splitter 51 travels along the same route of the measurement beam 241 in the first round (the reflecting mirror 53B, the λ/4 plate 54, the optical member 20B, the roof mirror 255, the optical member 20B, the λ/4 plate 54, and the reflecting mirror 53B), and then returns to the polarizing beam splitter 51. In the second round, the measurement beam 241 from the optical member 20B enters the λ/4 plate 54, passes therethrough, and is thereby converted to S polarized state light that has a polarized light direction that is the same as the original polarized light direction. And then, the measurement beam 241 is reflected by the polarizing separation surface 51S of the polarizing beam splitter 51, further proceeds in the +Y direction, and enters the photodetector 60.

On the optical paths of the reference beam 240 and the measurement beam 241 between the polarizing beam splitter 51 and the photodetector 60, as needed, there is provided with the adjusting mechanism 259. For example, the adjusting mechanism 259 can have at least one of an optical shift function of beam axis, and a reducing function.

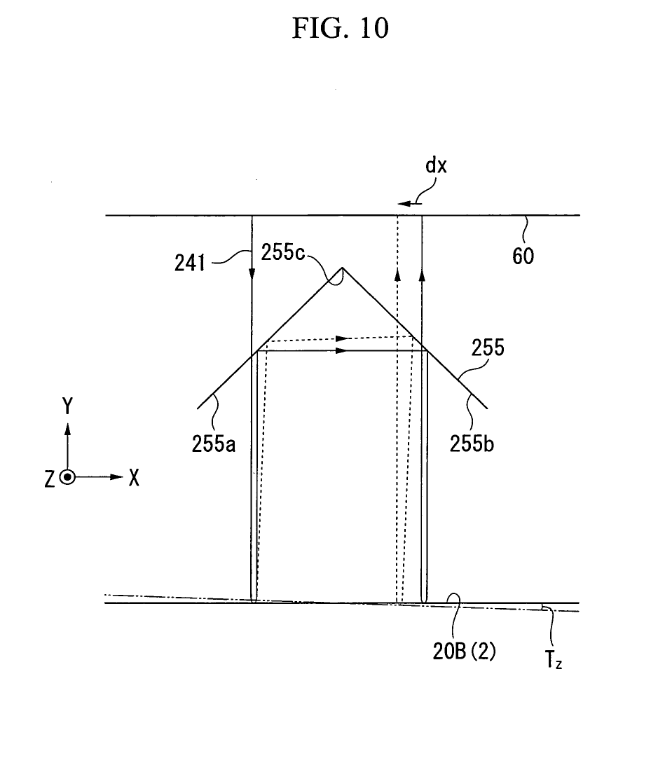

FIG. 10 schematically shows the change in the optical path of the measurement beam 241 in the Z interferometer system 13 when the attitude of the substrate stage 2 has changed. Furthermore, in FIG. 10, the optical path of the measurement beam 241 at the reference attitude is drawn with a solid arrow.

As shown in FIG. 10, if there is a change in the position in the rotational direction (yawing, rotation amount: Tz) of the substrate stage 2 about the Z axis, then the measurement beam 241 reflected by the optical member 20B is inclined with respect to the reference optical path in accordance with the rotation amount Tz of the substrate stage 2 about the Z axis, and enters the roof mirror 255, as shown by the broken line in FIG. 10. The incident angle of the measurement beam 241 with respect to each of the reflecting surfaces 255a, 255b of the roof mirror 255 differs from that of the reference optical path. Nevertheless, by being reflected twice by the roof mirror 255, the direction of the measurement beam 241 that returned from the roof mirror 255 to the optical member 20B is a direction that is parallel to the direction of the measurement beam 241 from the optical member 20B toward the roof mirror 255. Namely, even if the position of the substrate stage 2 about the Z axis changes, a state wherein the beam that enters the roof mirror 255 and the beam that emerges therefrom are parallel is maintained due to the retroreflection that is attendant with the shift of the optical axes of the beams in the roof mirror 255. The return measurement beam 241 from the optical member 20B enters the photodetector 60 at an angle that is the same as the reference optical path. Namely, with this Z interferometer system 13, an angular deviation of the measurement beam 241 in the return direction is substantially prevented even if the position of the substrate stage 2 (the optical member 20B) about the Z axis changes.

As described above, the reflecting surfaces (the first reflecting surface 21 and the second reflecting surface 22) of the optical member 20B are disposed parallel to the X axis and inclined from the XZ plane (refer to FIG. 8). Therefore, in addition to the rotation amount Tz about the Z axis (yawing), the similar retroreflection effect on the angular deviation by use of the roof mirror 255 can also be applied to the rotation amount Ty about the Y axis (rolling).

These are also applied to the reference beam 240 (refer to FIG. 8). Namely, due to the twice reflection on the roof mirror 254, an angular deviation of the reference beam 240 in the return direction is substantially prevented even if the position of the substrate stage 2 (the optical member 20B) about the Z axis or the Y axis changes.

Furthermore, as shown in FIG. 10, regarding the measurement beam 241 (the reference beam 240) returning from the optical member 20B, the yawing of the substrate stage 2 (the optical member 20B) induces a positional deviation dx along the X axis arises with respect to the reference optical path. The adjusting mechanism 259 as shown in FIG. 8 can have a configuration that reduces this positional deviation dx. Also, the adjusting mechanism 259 can have a configuration that reduces the positional deviation, which is associated with the rolling, of the beam along the Z axis.

Furthermore, regarding the rotation amount Tx about the X axis (pitching), as shown in FIG. 8, the angular deviation is substantially prevented by the twice reflection on the optical member 20B with the first reflecting surface 21 and the second reflecting surface 22. Namely, even if the position of the substrate stage 2 (the optical member 20B) about the X axis changes, due to the twice reflection, an angular deviation of the measurement beam 241 in the return direction from the optical member 20B to the roof mirror 255 is substantially prevented, and an angular deviation of the measurement beam 241 in the return direction from the optical member 20B to the polarizing beam splitter 51 is substantially prevented. Furthermore, regarding the measurement beam 241 from the optical member 20B, even if the incident position along the Z axis changes of the roof mirror 255 with respect to the reference optical path in association with the pitching of the substrate stage 2 (the optical member 20B), the returning measurement beam 241, which travels along the same route, from the roof mirror 255 can offset the positional deviation in the Z axis. Namely, with this Z interferometer system 13, a positional deviation of the beam along the Z axis in association with the pitching, and an angular deviation about the X axis is substantially avoided.

In the embodiment, the Z interferometer system 13 can have advantages such that: an angular deviation or a positional deviation of the beam caused by the pitching can be substantially prevented; an alignment error caused by change of attitude of the roof mirrors 254, 255 can be substantially prevented; and high degree of precision can be obtained by means of the double-pass method.

In the embodiment, the roof mirror 254, which serves as fixed mirror for the reference beam 240, and the roof mirror 255, which serves as fixed mirror for the measurement beam 241, are disposed substantially symmetrical with respect to the Z axis and with the central position of the optical member 20B in the Z axis therebetween. Therefore, the variation of the relative difference between the optical path length of the measurement beam 241 and the optical path length of the reference beam 240 with respect to the movement of the optical element 20B (the substrate stage 2) along the Z axis is relatively large, as a result, the minute position change of the substrate stage 2 can be detected with high accuracy.

Furthermore, in the embodiment, the measurement beam 241 and the reference beam 240 travel along the similar optical routes, therefore, the optical path length (a first route distance) of the measurement beam 241 and the optical path length (a second route distance) of the reference beam 240 are at the same level. As a result, when the inclination of the substrate stage 2, which serves as the measurement target, is changed, the returning beams of the measurement beam 241 and the reference beam 240 would have similar positional deviations. The assured interference of the beams provides an advantage of reducing the detection error and the measurement error.

Returning to FIG. 8, the photodetector 60 receives the reference beam 240 (returning beam) and the measurement beam 241 (returning beam) form the polarizing beam splitter 51. In the Z interferometer system 13, the positional information of the optical member 20B (the substrate stage 2 (refer to FIG. 1)) in the Z axis direction is measured based on the reference beam 240 and the measurement beam 241, which have entered the photodetector 60. As the position of the optical member 20B (the substrate stage 2) in the Z axis direction changes, the optical path length of the reference beam 240 and the measurement beam 241 change. In the Z interferometer system 13, based on the variation of the optical path length, the positional information of the optical member 20B (the substrate stage 2) in the Z axis direction can be obtained. Namely, if the optical member 20B (the substrate stage 2) moves along the Z axis, then the difference between the optical path length of the measurement beam 241 (the first route distance) and the optical path length of the reference beam 240 (the second route distance) fluctuates. Based on a reference signal and a measurement signal, which is obtained based on the fluctuations, Z interferometer system 13 can measure the position of the optical member 20B (the substrate stage 2) in the Z axis.

In this embodiment, an example was explained in which the optical member 20 (the optical member 20B) is positioned on the substrate stage 2; of course, the optical member 20 (the optical member 20B) can be positioned on the mask stage 1. In this case, the mask stage interferometer system 3M employs a Z interferometer system 13 such as that explained referring to FIG. 4 and FIG. 5.

As the substrate P in the above-described embodiments, in addition to a semiconductor wafer for semiconductor device manufacture, a glass substrate for a display device, a ceramic wafer for a thin film magnetic head, a master mask or reticle (synthetic quartz, silicon wafer) for use in an exposure apparatus, a film member, or similar may be employed. The substrate is not limited to circular shape; rectangular or other shapes can be used.

As the exposure apparatus EX, in addition to a step-and-scan type scanning exposure apparatus (scanning stepper) which moves a mask M and substrate P synchronously to scan and expose the substrate P to the pattern of the mask M, the invention can also be applied to a step-and-repeat type projection exposure apparatus (stepper), which, with the mask M and substrate P in the stationary state, performs one-shot exposure of the pattern of the mask M, and performs sequential step movement of the substrate P.

Further, in step-and-repeat exposure, with a first pattern and the substrate P substantially in the stationary state, a reduced image of the first pattern may be transferred onto the substrate P using a projection optical system, after which, with a second pattern and the substrate P substantially in the stationary state, a reduced pattern of the second pattern may be transferred using a projection optical system onto the substrate P, partially overlapping the first pattern, in one-shot exposure (switch-type one-shot exposure apparatus). As the stitching type exposure apparatus, the invention can also be applied to a step-and-stitch type exposure apparatus, in which at least two patterns are transferred with partial overlap onto the substrate P, and the substrate P is sequentially moved.

Further, this invention can also be applied to an exposure apparatus in which, as disclosed in U.S. Pat. No. 6,611,316, two mask patterns are merged on a substrate via a projection optical system, and one shot region on a substrate is exposed twice substantially simultaneously through a single scanning exposure.

Further, this invention can also be applied to a twin-stage type exposure apparatus having a plurality of substrate stages, such as disclosed in U.S. Pat. No. 6,341,007, U.S. Pat. No. 6,400,441, U.S. Pat. No. 6,549,269, U.S. Pat. No. 6,590,634, U.S. Pat. No. 6,208,407, U.S. Pat. No. 6,262,796, and similar.

Further, this invention can also be applied to an exposure apparatus having a substrate stage holding a substrate and a measurement stage equipped with a reference member on which is formed a reference mark and/or various electrooptic sensors, as disclosed for example in Japanese Patent Application Publication No. 11-135400 A (corresponding PCT International Patent Publication WO 1999/23692) and U.S. Pat. No. 6,897,963, and similar. Moreover, this invention can also be applied to an exposure apparatus provided with a plurality of substrate stages and measurement stages.

As the exposure apparatus EX, the invention can be applied not only to exposure apparatuses for semiconductor device manufacture which expose a substrate P to a semiconductor device pattern, but also to a wide range of exposure apparatuses for the manufacture of liquid crystal display elements or displays, as well as to exposure apparatuses for the manufacture of image capture devices (CCDs), micromachines, MEMS, DNA chips, as well as reticles and masks.

In each of the above-described embodiments, examples were explained for an exposure apparatus provided with a projection optical system PL; however, this invention can be applied to an exposure apparatus and exposure method not using a projection optical system PL. Even when such a projection optical system PL is not used, the substrate is irradiated with exposure light EL via a lens or other optical member.

As explained above, in one embodiment, an exposure apparatus EX is manufactured by assembling various subsystems, including each of the constituent components, so as to maintain prescribed mechanical tolerances, electrical tolerances, and optical tolerances. In order to secure these various tolerances, before and after the assembly, adjustments to attain optical precision of each of the optical systems, adjustments to attain mechanical precision of each of the mechanical systems, and adjustments to attain electrical precision of each of the electrical systems, are performed. Processes to assemble the several subsystems into an exposure apparatus include mechanical connection, wiring connection of electrical circuits, conduit connection between electrical circuits, and similar between the several subsystems. Prior to the process of assembling the several subsystems into an exposure apparatus, of course, processes to assemble each of the subsystems must be performed. When the process to assemble the subsystems into an exposure apparatus is completed, comprehensive adjustments are performed, and the precisions of the exposure apparatus as a whole are secured. It is desirable that the exposure apparatus be manufactured in a clean room in which the temperature, cleanliness, and other parameters are controlled.

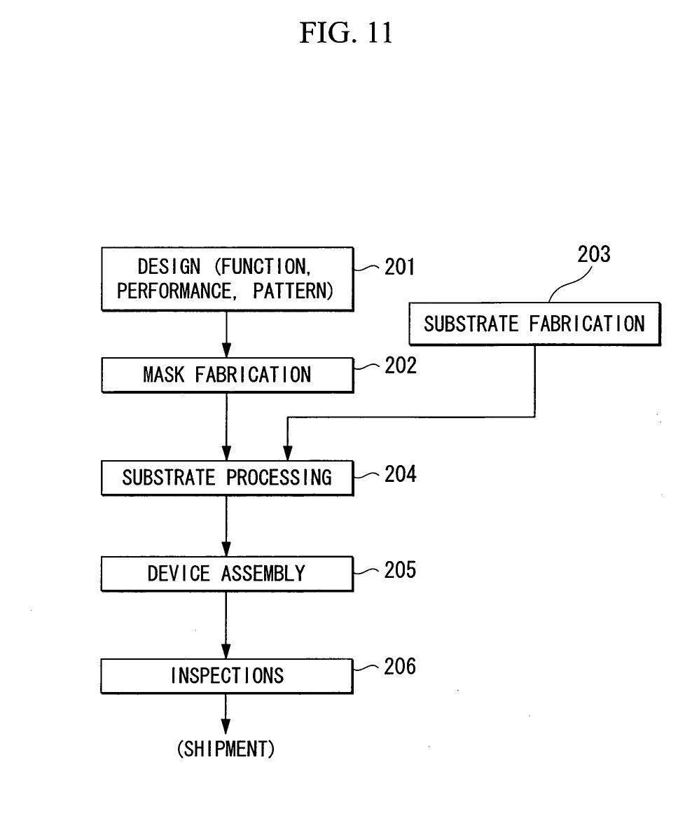

As shown in FIG. 11, semiconductor devices and other microdevices are manufactured by performing a step 201 of function and performance design of the microdevice; a step 202 of fabricating a mask (reticle) based on the design step; a step 203 of fabricating the substrate which is the base for the device; a step 204 of substrate processing, including exposing the substrate to an image of the mask pattern, according to the above-described embodiments, and developing the exposed substrate (exposure processing); a device assembly step 205 (including a dicing process, bonding process, packing process, and other processes); an inspection step 206; and similar.

As far as is permitted, the disclosures in all of the Publications and U.S. patents related to exposure apparatuses and the like cited in the above respective embodiments and modified examples, are incorporated herein by reference.

In the above, embodiments of the invention have been explained; however, in this invention the various constituent elements described above can be combined as appropriate and used, and moreover there may be cases in which a portion of the constituent elements is not used.

What is claimed is:

1. An optical member that is irradiated with light to measure position information in a first direction, the optical member comprising:
a first reflecting surface, onto which light propagating in a second direction intersecting the first direction, is incident; and
a second reflecting surface, onto which light propagating in the second direction, is incident,
wherein
the first reflecting surface and the second reflecting surface are optically connected, and light reflected by one of the first reflecting surface and the second reflecting surface is incident on the other reflecting surface.

2. The optical member according to claim 1, wherein
the first reflecting surface is substantially parallel to a plane, resulting from inclination of the plane containing a first axis parallel to the first direction and a third axis parallel to a third direction orthogonally intersecting the first direction and the second direction, through a first angle about the third axis,
the second reflecting surface is substantially parallel to a plane, resulting from inclination of the plane containing the third axis and the first axis, through a second angle about the third axis and,
the angle made by the first reflecting surface and the second reflecting surface is other than 90°, and is smaller than 180°.

3. An interferometer system that measures position information of a mobile body in a first direction, the interferometer system comprising:
a first emission portion, which emits measurement light;
a second emission portion, which emits reference light;
a first reflecting surface that is disposed on the mobile body and onto which the measurement light from the first emission portion, which is propagating in a second direction intersecting the first direction, is incident;
a second reflecting surface that is disposed on the mobile body and onto which the reference light from the second emission portion, which is propagating in the second direction, is incident;
a third reflecting surface that is optically connected to the second reflecting surface and that is substantially stationary in a first position; and
a fourth reflecting surface that is optically connected to the first reflecting surface and that is substantially stationary in a second position,
wherein
the first reflecting surface and the second reflecting surface are optically connected, and light reflected by one of the first reflecting surface and the second reflecting surface is incident on the other reflecting surface.

4. The interferometer system according to claim 3, wherein
the first reflecting surface is substantially parallel to a plane, resulting from inclination of the plane containing a first axis parallel to the first direction and a third axis parallel to a third direction orthogonally intersecting the first direction and the second direction, through a first angle about the third axis;
the second reflecting surface is substantially parallel to a plane, resulting from inclination of the plane containing the third axis and the first axis, through a second angle about the third axis; and
the angle made by the first reflecting surface and the second reflecting surface is other than 90°, and is smaller than 180°.

5. The interferometer system according to claim 3, wherein
the first reflecting surface and the second reflecting surface are formed in a prescribed optical member, and
the optical member is disposed on the mobile body.

6. The interferometer system according to claim 3, wherein
the measurement light, which is reflected by the first reflecting surface and via the second reflecting surface, is incident on the third reflecting surface, and
the reference light, which is reflected by the second reflecting surface and via the first reflecting surface, is incident on the fourth reflecting surface.

7. The interferometer system according to claim 6, wherein
the third reflecting surface and the fourth reflecting surface are each planar,
the measurement light from the second reflecting surface is incident substantially perpendicularly on the third reflecting surface, and
the reference light from the first reflecting surface is incident substantially perpendicularly on the fourth reflecting surface.

8. The interferometer system according to claim 3, wherein
the third reflecting surface and the fourth reflecting surface are each planar, and
an optical system is provided in which the measurement light makes at least two round trips in a route comprising the third reflecting surface and the reference light makes at least two round trips in a route comprising the fourth reflecting surface.

9. The interferometer system according to claim 3, wherein
the measurement light, which is reflected by the third reflecting surface and via the second reflecting surface, is incident on the first reflecting surface, and
the measurement light, which is reflected by the fourth reflecting surface and via the first reflecting surface, is incident on the second reflecting surface.

10. The interferometer system according to claim 3, further comprising a photodetector, onto which the measurement light, after reflection by the third reflecting surface and reflection by the second reflecting surface, and then reflection by the first reflecting surface, is incident, and onto which the reference light, after reflection by the fourth reflecting surface and reflection by the first reflecting surface, and then reflection by the second reflecting surface, is incident.

11. A stage apparatus comprising:
a stage that is movable in a prescribed plane substantially perpendicular to the first direction; and
the optical member according to claim 1, disposed on the stage.

12. A stage apparatus comprising:
a stage that is movable in a prescribed plane substantially perpendicular to the first direction; and
the interferometer system according to claim 3, to measure position information for the stage in the first direction.

13. An exposure apparatus that exposes a substrate with exposure light via a mask having a pattern, the exposure apparatus comprising:
a mask stage that moves while holding the mask; and
a substrate stage that moves while holding the substrate,
wherein
at least one of the mask stage and the substrate stage comprises the stage apparatus according to claim 11.

14. A device manufacturing method, comprising:
exposing a substrate using the exposure apparatus according to claim 13; and
developing the exposed substrate.

15. An interferometer system for measuring a position of a mover along a first axis, the interferometer system comprising:
a co-ordinate system comprising the first axis, a second axis, which is orthogonal to the first axis, and a third axis, which is orthogonal to the first axis and the second axis;
a first member that is disposed on the mover;
a second member and a third member that are disposed apart from the mover along the second axis;
a first route for a measurement beam, the first route comprising a successive two time reflection on the first member by which the measurement beam is bent about the third axis, and an at least one time reflection on the second member by which the measurement beam from the first member is returned to the first member; and
a second route for a reference beam, the second route comprising a successive two time reflection on the first member by which the reference beam is bent about the third axis, and an at least one time reflection on the third member by which the reference beam from the first member is returned to the first member.

16. The interferometer system according to claim 15, wherein a difference between a distance of the first route and a distance of the second route fluctuates along with a movement of the mover along the first axis.

17. The interferometer system according to claim 15, wherein at least one of the first route and the second route further comprises another successive two time reflection on the first member by which the measurement beam or the reference beam is bent about the third axis.

18. The interferometer system according to claim 15, wherein the second member and the third member are separately disposed with a plane therebetween and next to the both sides of the plane, which includes the second axis and the third axis and intersects an optical central position of the optical member in the first axis.

19. The interferometer system according to claim 15, wherein the measurement beam and the reference beam make two round trips along the first route or the second route.

20. The interferometer system according to claim 15, further comprising a fourth member by which at least one optical axis of the measurement beam and the reference beam parallel shifts along the third axis.

21. The interferometer system according to claim 15, wherein, in the successive two reflection on the first member in at least one of the first route and the second route, a total rotation amount about the third axis is greater than or equal to 160° and less than or equal to 260°.

22. The interferometer system according to claim 15, wherein the at least one time reflection on the second member and the at least one time reflection on the third member comprise a successive two time reflection on the second member or the third member.

23. The interferometer system according to claim 22, wherein, in the successive two reflection on the second member or the third member, a total rotation amount about the first axis is approximately 180°.
